(19) United States
(12) Patent Application Publication
(10) Pub. No.: US 2026/0058743 A1
(43) Pub. Date: Feb. 26, 2026

(54) Harmonic Leakage Rejection for Wireless Circuitry

(71) Applicant: Apple Inc., Cupertino, CA (US)

(72) Inventors: Jong Seok Park, San Diego, CA (US); Zhengan Yang, Del Mar, CA (US); Youngchang Yoon, San Diego, CA (US); Hamidreza Kazemi Varnamkhasti, San Diego, CA (US)

(21) Appl. No.: 18/814,215

(22) Filed: Aug. 23, 2024

(51) Int. Cl. H04B 17/354

(52) U.S. Cl. CPC H04B 17/354

(57) ABSTRACT

Wireless circuitry is provided that includes a radio-frequency amplifier and a passive network coupled to the radio-frequency amplifier. The passive network includes a primary coil, a secondary coil magnetically coupled to the primary coil, and a harmonic rejection component coupled between the primary coil and the secondary coil and configured to reject harmonic signals produced by the radio-frequency amplifier. The harmonic rejection component can be a capacitor. The harmonic rejection component can be configured to operate as an open circuit at a first frequency and can further be configured to resonate with a portion of the secondary coil at a second frequency different than the first frequency.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver. If care is not taken, radio-frequency amplifier circuitry can produce harmonic leakage resulting in undesired spurious emissions at the antenna.

### SUMMARY

An aspect of the disclosure provides wireless circuitry that includes a radio-frequency amplifier and a passive network coupled to the radio-frequency amplifier. The passive network includes a primary coil having opposing terminals coupled to the radio-frequency amplifier, a secondary coil magnetically coupled to the primary coil, and a harmonic rejection component coupled between the primary coil and the secondary coil and configured to reject harmonic signals produced by the radio-frequency amplifier. The secondary coil can have a first terminal coupled to an antenna and a second terminal coupled to a ground power supply line. The harmonic rejection component can include a capacitor having a first terminal coupled to a node disposed between a first coil portion of the secondary coil and a second coil portion of the secondary coil. The capacitor can have a second terminal coupled to a center tap of the primary coil. The harmonic rejection component can be configured to reject third harmonic signals produced by the radio-frequency amplifier.

An aspect of the disclosure provides a passive network that includes a primary coil coupled to an amplifier, a secondary coil coupled to an antenna, and a harmonic rejection component having a first terminal coupled to a node in the primary coil and having a second terminal coupled to a node in the secondary coil, where the harmonic rejection component is configured to operate as an open circuit at a first frequency and is further configured to resonate with a portion of the secondary coil at a second frequency different than the first frequency. The harmonic rejection component can include a capacitor having a first terminal coupled to a center tap of the primary coil and a second terminal coupled to a node disposed between the portion of the secondary coil and another portion of the secondary coil. The portion of the secondary coil can be shunted to a ground line.

An aspect of the disclosure provides a circuit that includes a balun having a first coil and a second coil and a harmonic rejection component having a first terminal coupled to a first node in the first coil and having a second terminal coupled to a second node in the second coil. The harmonic rejection component can be configured to operate as an open circuit at a first frequency and can be further configured to resonate with a portion of the second coil at a second frequency different than the first frequency.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having transmit and receive circuits in accordance with some embodiments.

FIG. 3 is a diagram of illustrative passive matching network coupled between an amplifier and an antenna in accordance with some embodiments.

FIG. 4 is a diagram plotting third harmonic distortion (HD3) versus second harmonic distortion (HD2) in accordance with some embodiments.

FIG. 5 is a diagram showing an equivalent circuit of the passive matching network of FIG. 3 operated in a differential mode in accordance with some embodiments.

FIG. 6 is a diagram showing an equivalent circuit of the passive matching network of FIG. 3 operated in a common mode in accordance with some embodiments.

FIG. 7 is a diagram plotting signal gain as a function of frequency for differential and common mode signals in accordance with some embodiments.

### DETAILED DESCRIPTION

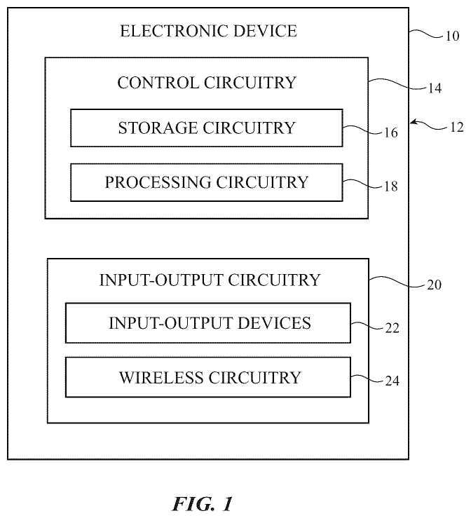

An electronic device such as device 10 of FIG. 1 may be provided with wireless circuitry that includes one or more harmonic filtering components. The wireless circuitry may include an antenna, a radio-frequency transmitting amplifier configured to amplify radio-frequency signals for transmission at the antenna, and an output network coupled between the radio-frequency amplifier and the antenna. The output network may be a transformer (balun) based impedance matching network. The output network can include a primary coil configured to receive a differential signal, a secondary coil coupled between the antenna and a ground line, and a harmonic rejection component coupled between the primary coil and the secondary coil. The harmonic rejection component can be a capacitor having a first terminal coupled to a center tap of the primary coil and having a second terminal coupled to some point along the winding of the secondary coil. An output network configured in this way is technically advantageous and beneficial to provide third harmonic filtering without degrading second harmonic rejection.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

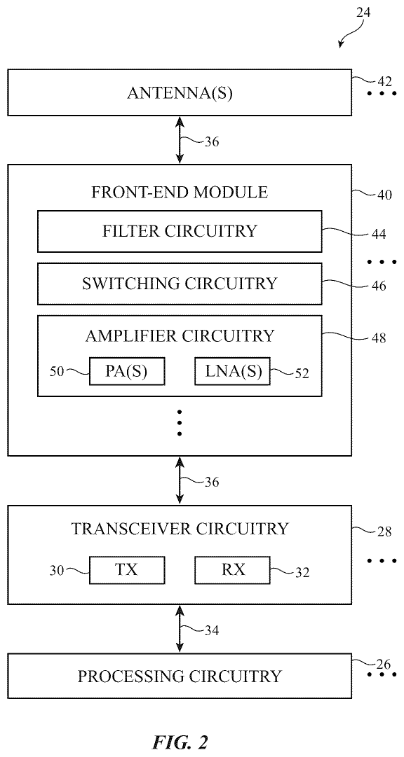

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may include a baseband processor, application processor, general purpose processor, microprocessor, microcontroller, digital signal processor, host processor, application specific signal processing hardware, and/or other types of processor. Processing circuitry 26 may be coupled to transceiver 28 over path 34. Transceiver 28 may be coupled to antenna 42 via radio-frequency transmission line path 36. Radio-frequency front-end module 40 may be disposed on radio-frequency transmission line path 36 between transceiver 28 and antenna 42.

In the example of FIG. 2, wireless circuitry 24 is illustrated as including only a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide transmit signals (e.g., digital or baseband signals) to transceiver 28 over path 34. Transceiver 28 may further include circuitry for converting the transmit (baseband) signals received from processing circuitry 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processing circuitry 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front-end module 40. Transceiver 28 may include circuitry such as receiver (RX) 32 for receiving signals from front-end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processing circuitry 26 over path 34.

Front-end module (FEM) 40 may include radio-frequency front-end circuitry that operates on the radio-frequency signals conveyed (transmitted and/or received) over radio-frequency transmission line path 36. FEM 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip. If desired, amplifier circuitry 48 and/or other components in front-end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front-end module 40. For example, transceiver 28 may be formed on another substrate such as the main logic board of device 10, a rigid printed circuit board, or flexible printed circuit that is not a part of front-end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front-end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHZ WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

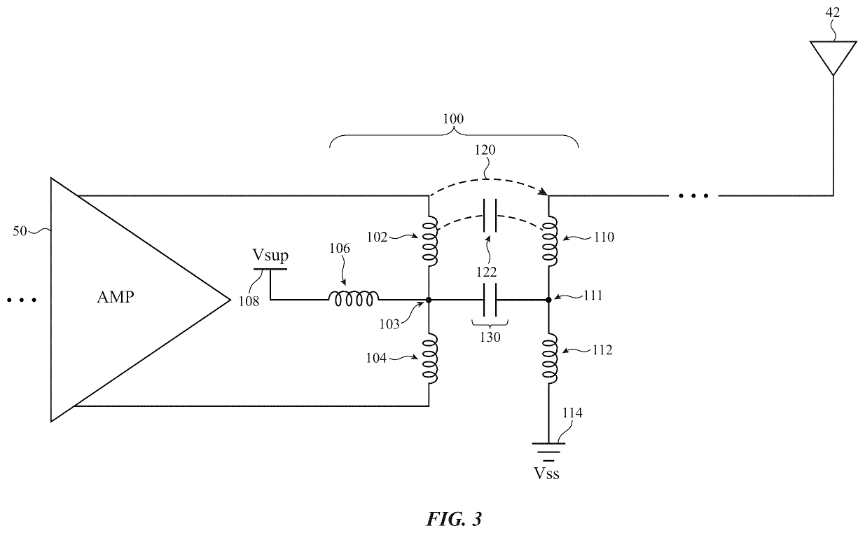

FIG. 3 is a diagram of illustrative passive output network such as output network 100 coupled between radio-frequency amplifier 50 and one or more antennas 42. Radio-frequency amplifier 50 may be a transmitting (power) amplifier described in connection with FIG. 2. Radio-frequency amplifier 500 can have a differential output (port) and can be configured to output differential radio-frequency signals on its differential output port. Output network 100 can be configured as an impedance matching network configured to provide optimal power transfer between radio-frequency amplifier 50 and antenna 42. Output network 100 can be configured to provide a target amount of impedance termination for antenna 42 (e.g., to provide a 50 Ohm impedance, a 75 Ohm impedance, a 100 Ohm impedance, less than 50 Ohms of impedance, greater than 50 Ohms of impedance, 50-100 Ohms of impedance, less than 100 Ohms of impedance, or more than 100 Ohms of impedance).

As shown in FIG. 3, output network 100 can include a primary coil (winding) having primary coil portions 102 and 104 and a secondary coil (winding) having secondary coil portions 110 and 112. The primary coil can have a center tap at node 103 that is disposed between first primary coil portion 102 and second primary coil portion 104. Since node 103 disposed between coil portions 102 and 104 is the center tap node of the primary coil, the inductance value of coil portion 102 is thus equal to the inductance value of coil portion 104. The output network 100 can further include an inductor such as inductor 106 coupled to the center tap node 103. In particular, inductor 106 can have a first terminal coupled to center tap 103 of the primary coil and can have a second terminal coupled to a power supply line 108 (e.g., a positive power supply terminal on which positive power supply voltage Vsup is provided). This is exemplary. If desired, the second terminal of inductor 106 can alternatively be coupled to a ground power supply line, a reference voltage line, or other static voltage line. In other embodiments, a parasitic routing path can be used in place of inductor 106.

The secondary coil having secondary coil portions 110 and 112 can have a first terminal coupled to antenna 42 and a second terminal coupled to ground power supply line 114 (e.g., a ground power supply terminal on which ground voltage Vss is provided). The primary coil and the secondary coil can form part of a transformer. In particular, such type of transformer in which one side (e.g., the primary side) is coupled to a differential port and in which the other side (e.g., the secondary side) has one end that is shunted to ground is sometimes referred to and defined herein as a “balun.” Thus, such type of impedance matching network 100 is sometimes referred to herein as a transformer based output network or a balun based output network. Output network 100 that includes only passive electrical components (e.g., inductor and capacitor components, and optionally one or more resistor components) is sometimes referred to as a “passive” matching network.

Radio-frequency amplifier 50 can be configured to process or output signals at frequency f₀. Frequency f₀ can be referred to herein as a fundamental (radio) frequency. The term “harmonic” signals can refer to signals having a frequency that is equal to some integer multiple of an associated fundamental frequency. Amplifiers, in general, have a linear operating range and a non-linear operating range. To avoid signal distortion, amplifiers are often operated in the linear range. When operated in the non-linear range, the ratio of input power to output power may not be constant. Thus, as the input signal amplitude increases, a disproportionate increase in the output signal amplitude and/or phase may occur. The non-linear behavior of such system can sometimes produce undesired harmonic signals such as second harmonic signals (e.g., spurious signals at the second harmonic frequency 2*f₀) and third harmonic signals (e.g., spurious signals at the third harmonic frequency 3*f₀). Signal interference or distortion caused by the second harmonic signals can be referred to herein as second harmonic distortion (HD2), whereas signal interference or distortion caused by the third harmonic signals can be referred to herein as third harmonic distortion (HD3). Harmonic signals not only distort the desired signal but can also leak to the antenna, violating stringent emission spectrum criteria. Such harmonics generated by amplifier 50 can be filtered out by output network 100.

Still referring to FIG. 3, the primary coil can be magnetically coupled to the secondary coil, as illustrated by magnetic coupling line 120. The windings of the primary coil and the windings of the secondary coil can also at least partially overlap with each other (e.g., the primary coil portions 102 and/or 104 can be formed directly above or below at least part of the secondary coil portions 110 and 112). Such overlapping in the windings of the primary and secondary coils can result in distributed capacitive coupling along the windings, as schematically illustrating by capacitive coupling line 122.

The magnetic coupling between the primary and secondary coil windings induces current to flow in the opposite (equal and opposite) directions, creating a “balanced” signal behavior. In contrast, the capacitive coupling between the primary and secondary coil windings results in an “unbalanced” signal behavior as perceived across the differential terminals of the primary coil (e.g., the positive terminal can perceive a small AC signal while the negative can perceive a virtual ground voltage). In general, a balanced (symmetrical) signal behavior in the transformer based output network 100 is desired for optimal HD2 (leakage) rejection, whereas an unbalanced (asymmetrical) signal behavior in the transformer based output network 100 is desired for optimal HD3 (leakage) rejection.

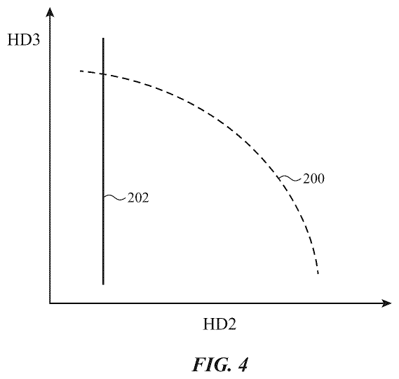

This desire for a symmetrical signal behavior for mitigating HD2 and the desire for an asymmetrical signal behavior for mitigating HD3 can impose a design-limiting tradeoff between HD2 and HD3 rejection. This tradeoff is illustrated in FIG. 4. FIG. 4 is a diagram plotting third harmonic distortion (HD3) versus second harmonic distortion (HD2). Curve 200 illustrates the tradeoff between HD2 and HD3 for a conventional transformer based output network. As shown by curve 200, decreasing HD2 would necessarily increase HD3, whereas decreasing HD3 would necessarily increase HD2. It would therefore be desirable to provide a technique that can allow for simultaneous reduction of HD2 and HD3, or at least allow for the reduction of HD3 without degrading HD2.

Referring back to FIG. 3, output network 100 can be configured with harmonic rejection capabilities (e.g., to reject undesired harmonic signals) in accordance with some embodiments. The term “harmonic rejection” can generally refer to and be defined herein as an act of rejecting or filtering harmonic signals, which can include second harmonic signals with the second harmonic frequency 2*f₀, third harmonic signals with the third harmonic frequency 3*f₀, fourth harmonic signals with a fourth harmonic frequency 4*f₀, fifth harmonic signals with a fifth harmonic frequency 5*f₀, and other higher order harmonic signals. In particular, output network 100 can include a harmonic rejection component such as harmonic rejection component 130 coupled (interposed) between the primary coil and the secondary coil of the transformer/balun. Harmonic rejection component 130 can be a capacitor having a first terminal coupled to center tap 103 of the primary coil and having a second terminal coupled to node 111 along the secondary coil. Node 111 can be but need not be at the center tap of the secondary coil. In other words, node 111 can be disposed at any position along the winding(s) of the secondary coil. In scenarios where node 111 is not at the center tap of the secondary coil, the inductance (value) of coil portion 110 will be different than the inductance (value) of coil portion 112.

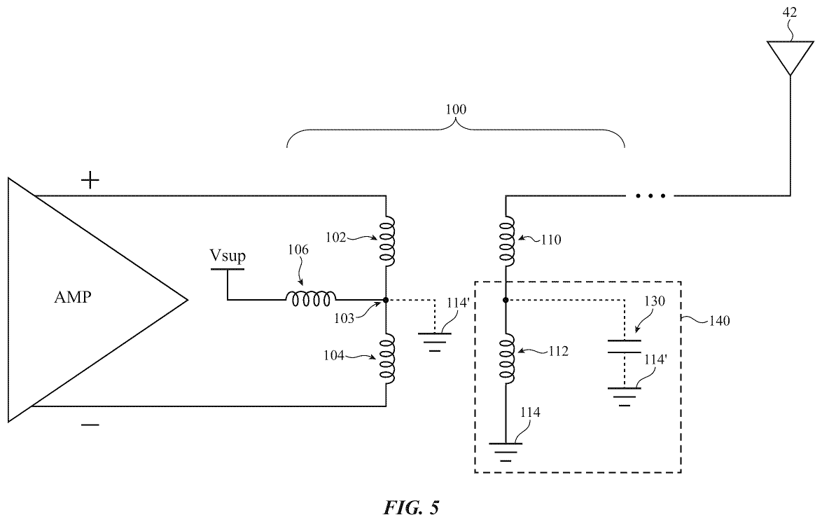

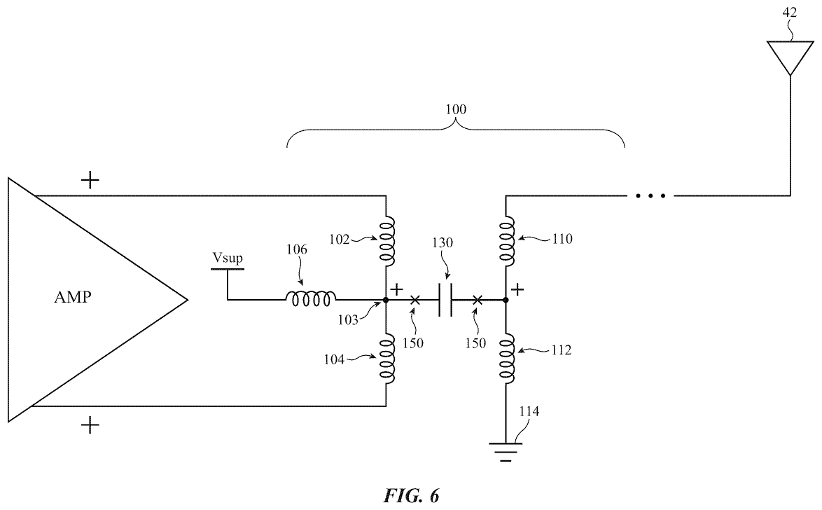

The operation of output network 100 in the context of HD2 and HD3 is best understood in conjunction with FIGS. 5 and 6. FIG. 5 is a diagram showing an equivalent circuit of the output network 100 operated in a differential mode. As described above, asymmetrical signal behavior is related to HD3, which can be analyzed when output network 100 is operated in the differential mode. As shown in FIG. 5, in the differential mode of operation, center tap node 103 can behave like a virtual ground node (see, e.g., virtual ground 114′). In analog (small) signal processing, the term “virtual ground” can refer to and be defined herein as a point in a circuit that is maintained at a stable voltage or reference level but is not physically connected to a ground line. This will effectively shunt capacitor 130 to virtual ground 114′. Operated in this way, capacitor 130 and coil portion 112 can form a parallel resonant (tank) circuit 140 configured to resonate at a given resonant frequency. In other words, resonant tank 140 can include capacitor 130 and only portion 112 of the secondary coil. The resonant frequency can be calculated as follows:

$$2 π ( 3 * {f}_{0} ) = 1 / ( Ls * Cx ) \qquad ( 1 )$$

where Ls represents the inductance of secondary coil portion 112 and where Cx represents the capacitance of capacitor 130. By setting Ls and Cx to be a function of the third harmonic frequency 3*f₀, the resonant tank circuit 140 can be configured to resonate at the third harmonic frequency and can behave like an open circuit at the third harmonic frequency. In other words, capacitor 130 can be configured to provide HD3 rejection to prevent undesired third harmonic signals from leaking into antenna 42. Capacitor 130 can thus sometimes be referred to as an HD3 rejection or filtering component.

The example above in which capacitor 130 is configured to provide HD3 rejection is illustrative. As another example, capacitor 130 can alternatively be configured to provide HD5 rejection (e.g., by plugging 5*f₀ into equation 1 above and setting the Ls and Cx values accordingly). As another example, capacitor 130 can alternatively be configured to provide HD7 rejection (e.g., by plugging 7*f₀ into equation 1 above and setting the Ls and Cx values accordingly). In general, capacitor 130 can be configured to provide “odd” harmonic signal rejection (e.g., to reject signals having frequencies equal to an odd multiple of the fundamental frequency).

In contrast, FIG. 6 is a diagram showing an equivalent circuit of the output network 100 operated in a common mode. As described above, symmetrical signal behavior is related to HD2, which can be analyzed when output network 100 is operated in the common mode. As shown in FIG. 6, in the common mode of operation, the second harmonic signals can leak from center tap node 103 to node 112 through capacitor 130. Such common mode behavior results in capacitor 130 effectively behaving like an open circuit between the series path from node 102 and 112, as denoted by circuit disconnection 150. Since capacitor 130 itself behaves like an open circuit component in the common mode, the addition of capacitor 130 to suppress HD3 will not affect HD2. In other words, the use of capacitor 130 can help decouple the design-limiting tradeoff between HD2 and HD3. Referring again to FIG. 4, curve 202 illustrates a relationship between HD2 and HD3 for passive output network 100 of the type described in connection with FIG. 6. As shown by curve 202, HD3 can be decreased without impacting HD2. In other words, the use of HD3 rejection capacitor 130 can provide HD3 mitigation without degrading HD2 (and without impacting HD4, HD6, or other “even” harmonic signal distortion for that matter). In other words, capacitor 130 can behave as an open circuit for signals having frequencies equal to an even multiple of the fundamental frequency.

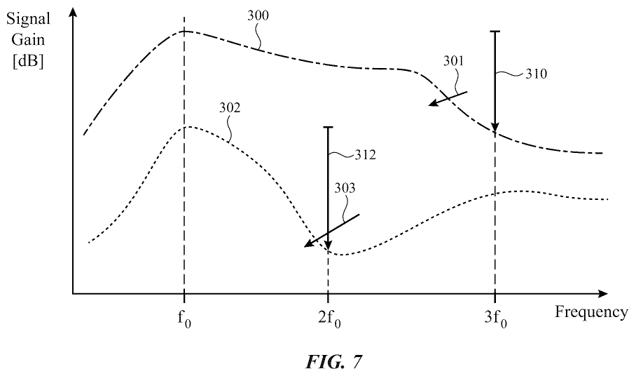

FIG. 7 is a diagram plotting signal gain as a function of frequency for differential and common mode signals in accordance with some embodiments. Curve 300 represents the differential mode gain profile as a function of frequency, whereas curve 302 represents the common mode gain profile as a function of frequency. As shown by curve 300, a high differential mode gain can be achieved at fundamental frequency f₀ while a substantial amount of HD3 rejection can be achieved at the third harmonic frequency 3*f₀, as illustrated by arrow 310. The amount of HD3 rejection can optionally be tuned by adjusting the capacitance of capacitor 130, as indicated by arrow 301. Capacitor 130 can be a fixed or adjustable capacitor. In some embodiments, capacitor 130 can be an adjustable capacitor implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. Moreover, as shown by curve 302, a substantial amount of HD2 rejection can be achieved at the second harmonic frequency 2*f₀, as illustrated by arrow 312. The amount of HD2 rejection can be minimally affected by adjusting the capacitance of capacitor 130, as indicated by arrow 303.

The methods and operations described above in connection with FIGS. 1-7 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry 26 in wireless circuitry 24, processing circuitry 18 of FIG. 1, etc.). The processing circuitry 26 may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Wireless circuitry comprising:
a radio-frequency amplifier; and
a passive network coupled to the radio-frequency amplifier, wherein the passive network comprises:
a primary coil having opposing terminals coupled to the radio-frequency amplifier;
a secondary coil magnetically coupled to the primary coil; and
a harmonic rejection component coupled between the primary coil and the secondary coil and configured to reject harmonic signals produced by the radio-frequency amplifier.

2. The wireless circuitry of claim 1, wherein the opposing terminals of the primary coil is coupled to a differential output port of the radio-frequency amplifier.

3. The wireless circuitry of claim 1, wherein the secondary coil comprises a first terminal coupled to an antenna and a second terminal coupled to a ground power supply line.

4. The wireless circuitry of claim 3, wherein the harmonic rejection component comprises a capacitor having a first terminal coupled to a node disposed between a first coil portion of the secondary coil and a second coil portion of the secondary coil.

5. The wireless circuitry of claim 4, wherein the first coil portion has a first inductance value, and wherein the second coil portion has a second inductance value different than the first inductance value.

6. The wireless circuitry of claim 4, wherein the first coil portion has a first inductance value, and wherein the second coil portion has a second inductance value equal to the first inductance value.

7. The wireless circuitry of claim 4, wherein the capacitor has a second terminal coupled to a center tap of the primary coil.

8. The wireless circuitry of claim 7, further comprising:
an inductor having a first terminal coupled to the center tap of the primary coil and having a second terminal coupled to an additional power supply line.

9. The wireless circuitry of claim 1, wherein the harmonic rejection component is configured to reject third harmonic signals produced by the radio-frequency amplifier.

10. The wireless circuitry of claim 1, wherein the radio-frequency amplifier is configured to output signals having a fundamental frequency, and wherein the harmonic rejection component comprises a capacitor configured to resonate with a portion of the secondary coil at a third harmonic frequency equal to three times the fundamental frequency.

11. A passive network comprising:
a primary coil coupled to an amplifier;
a secondary coil coupled to an antenna; and
a harmonic rejection component having a first terminal coupled to a node in the primary coil and having a second terminal coupled to a node in the secondary coil, wherein the harmonic rejection component is configured to operate as an open circuit at a first frequency and is further configured to resonate with a portion of the secondary coil at a second frequency different than the first frequency.

12. The passive network of claim 11, wherein the harmonic rejection component comprises a capacitor having a first terminal coupled to a center tap of the primary coil.

13. The passive network of claim 12, wherein the capacitor has a second terminal coupled to a node disposed between the portion of the secondary coil and another portion of the secondary coil.

14. The passive network of claim 12, further comprising:
an inductor having a first terminal coupled to the center tap of the primary coil and having a second terminal coupled to a power supply line.

15. The passive network of claim 11, wherein the portion of the secondary coil is shunted to a ground line.

16. The passive network of claim 11, wherein:
the amplifier is configured to process signals at a given frequency; and
the first frequency is equal to an even multiple of the given frequency.

17. The passive network of claim 16, wherein the second frequency is equal to an odd multiple of the given frequency.

18. A circuit comprising:
a balun having a first coil and a second coil; and
a harmonic rejection component having a first terminal coupled to a first node in the first coil and having a second terminal coupled to a second node in the second coil.

19. The circuit of claim 18, wherein the harmonic rejection component is configured to operate as an open circuit at a first frequency and is further configured to resonate with a portion of the second coil at a second frequency different than the first frequency.

20. The circuit of claim 18, wherein:
the first node is disposed between a first coil portion and a second coil portion;
the first and second coil portions of the first coil have equal inductance values;
the second node is disposed between a third coil portion and a fourth coil portion; and
the third and fourth coil portions of the second coil have different inductance values.
